(19) United States
(12) Patent Application Publication
(10) Pub. No.: US 2024/0334714 A1
(43) Pub. Date: Oct. 3, 2024

(54) METHOD OF MANUFACTURING SEMICONDUCTOR DEVICE USING ISOLATION STRUCTURE

(71) Applicant: SK hynix Inc., Icheon (KR)

(72) Inventors: Sang Gu YEO, Icheon (KR); Yong Jin JEONG, Icheon (KR)

(21) Appl. No.: 18/459,191

(22) Filed: Aug. 31, 2023

(30) Foreign Application Priority Data
Mar. 29, 2023 (KR) 10-2023-0041145

(51) Int. Cl. H10B 63/00; H01L 21/762

(52) U.S. Cl. CPC H10B 63/845; H01L 21/76224

(57) ABSTRACT

A manufacturing method may include forming an opening within a stack, forming a variable resistance layer within the opening and on the stack, forming a conductive layer on the variable resistance layer, forming a conductive pattern including a first part within the opening and a second part on the stack, by etching the conductive layer, forming a variable resistance pattern including a first part within the opening and a second part on the stack, by etching the variable resistance layer, and planarizing the conductive pattern and the variable resistance pattern until the stack is exposed.

### CROSS-REFERENCE TO RELATED APPLICATION

This application claims priority under 35 U.S.C. § 119 to Korean Patent Application No. 10-2023-0041145 filed on Mar. 29, 2023, which is incorporated herein by reference in its entirety.

### BACKGROUND

### 1. Technical Field

Embodiments relate to a planarization process method and, more particularly, to a method of manufacturing a semiconductor device using an isolation structure in a planarization process.

### 2. Related Art

Recently, as an electronic device is reduced in size, has low power consumption and high performance, and is diversified, a semiconductor device capable of storing information is required for various electronic devices, such as computers and portable communication devices. Accordingly, research is carried out on a semiconductor device capable of storing data by using a characteristic in which different resistance states are switched depending on a voltage or current applied to the semiconductor device. Such a semiconductor device includes resistive random access memory (RRAM), phase change random access memory (PRAM), ferroelectric random access memory (FRAM), magnetic random access memory (MRAM), and an E-fuse.

In order to reduce the size of a semiconductor device and increase the data storage capacity of the semiconductor device, the semiconductor device has been developed so that many memory cells are integrated in the same area by reducing a metal line width in a two-dimensional plane.

A method of manufacturing a semiconductor device as a three-dimensional structure is being researched and developed because of issues associated with manufacturing equipment, investment costs, and a development period as the metal line width in a two-dimensional plane is reduced.

### SUMMARY

In an embodiment, a manufacturing method may include forming an opening within a stack, forming a variable resistance layer within the opening and on the stack, forming a conductive layer on the variable resistance layer, forming a conductive pattern including a first part within the opening and a second part on the stack, by etching the conductive layer, forming a variable resistance pattern including a first part within the opening and a second part on the stack, by etching the variable resistance layer, and planarizing the conductive pattern and the variable resistance pattern until the stack is exposed.

In an embodiment, a method of manufacturing a semiconductor device may include forming a stack comprising first material layers and second material layers that are alternately stacked, forming an opening within the stack, forming a memory layer within the opening and on the stack, forming a first conductive layer on the memory layer, forming an isolation structure within the memory layer and the first conductive layer, and planarizing the first conductive layer, the memory layer, and the isolation structure until the stack is exposed.

In an embodiment, a method of manufacturing a semiconductor device may include forming a stack, forming an opening within the stack, forming a memory layer within the opening and on the stack, forming a conductive layer on the memory layer, forming conductive patterns and a trench that separates the conductive patterns from each other by etching the conductive layer, each of the conductive patterns comprising a first part within the opening and a second part that is connected to the first part and disposed over the stack, and forming an isolation structure within the trench.

### BRIEF DESCRIPTION OF THE DRAWINGS

FIGS. 1A, 2A, 3A, 4A, 5A, 6A, and 7A are cross-sectional views for describing a manufacturing method according to an embodiment of the present disclosure.

FIGS. 1B, 2B, 3B, 4B, 5B, 6B, and 7B are plan views for describing a manufacturing method according to an embodiment of the present disclosure.

FIGS. 8A and 8B are diagrams for describing a planarization process according to an embodiment of the present disclosure.

FIGS. 9A and 9B are plan views of isolation structures according to embodiments of the present disclosure.

FIGS. 10A and 10B are diagrams for describing semiconductor devices according to embodiments of the present disclosure.

FIGS. 11A, 11B, 11C, 11D, 11E, 11F, 11G, and 11H are diagrams for describing a method of manufacturing a semiconductor device according to an embodiment of the present disclosure.

### DETAILED DESCRIPTION

Hereinafter, embodiments according to the technical spirit of the present disclosure are described with reference to the accompanying drawings.

Embodiments of the present disclosure provide a manufacturing method for reducing a risk of a planarization process for materials having different hardness values and a method of manufacturing a semiconductor device using the manufacturing method.

It is possible to reduce a risk (e.g., film lifting) of a planarization process for materials having different hardness.

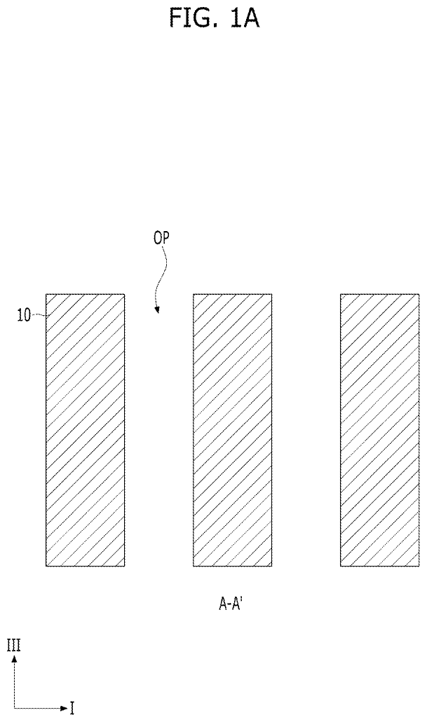

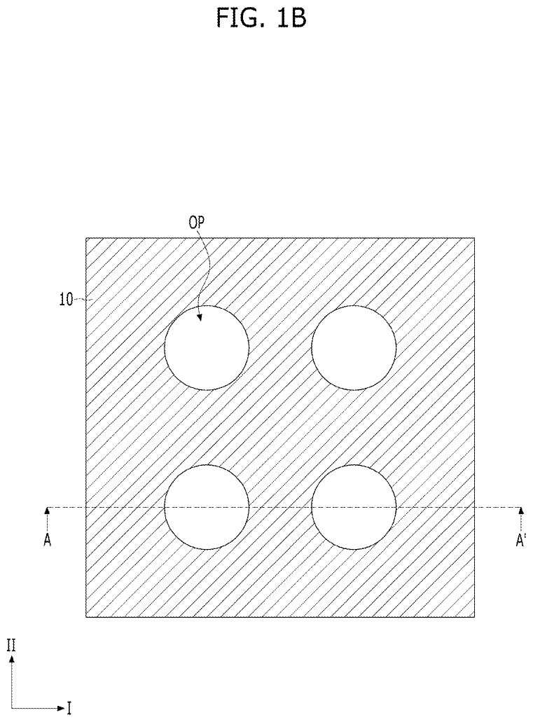

FIGS. 1A, 2A, 3A, 4A, 5A, 6A, and 7A are cross-sectional views for describing a manufacturing method according to an embodiment of the present disclosure. In this case, FIGS. 1A, 2A, 3A, 4A, 5A, 6A, and 7A may illustrate cross-sectional views of a semiconductor device according to a plane that is defined in a first direction I and a third direction III.

FIGS. 1B, 2B, 3B, 4B, 5B, 6B, and 7B are plan views of the semiconductor device for describing a manufacturing method according to an embodiment of the present disclosure. In this case, FIGS. 1B, 2B, 3B, 4B, 5B, 6B, and 7B may be plan views of the semiconductor device. FIGS. 1A, 2A, 3A, 4A, 5A, 6A, and 7A may be cross-sectional views taken along line A-A′ in FIGS. 1B, 2B, 3B, 4B, 5B, 6B, and 7B, respectively.

Referring to FIGS. 1A and 1B, a stack 10 may be formed. The stack 10 may include an insulating layer or may include a conductive layer. As an embodiment, the stack 10 may include first material layers and second material layers that have been alternately stacked. An opening OP may be formed within the stack 10. As an embodiment, a plurality of openings OP may be arranged in the first direction I and a second direction II that intersects the first direction I. The opening OP may extend in the third direction III within the stack 10. In this case, the third direction III may be a direction orthogonal to a plane that is defined in the first direction I and the second direction II.

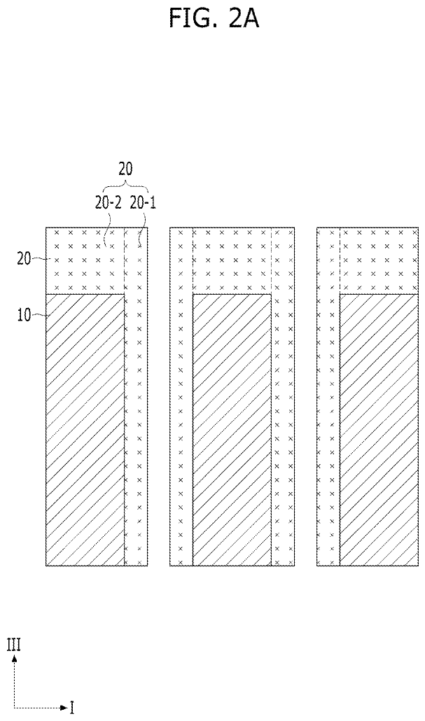

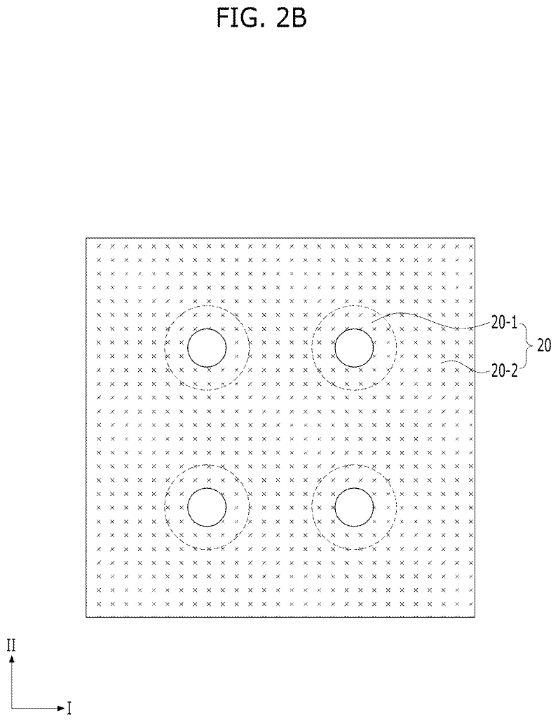

Referring to FIGS. 2A and 2B, a memory layer 20 may be formed. In this case, the memory layer 20 may include a floating gate, polysilicon, a charge trap material, nitride, a variable resistance material, or a phase change material. In an embodiment, the memory layer (e.g., variable resistance layer) 20 may be formed on the stack 10. When the present disclosure describes a first layer as being “on” or “over” a second layer, it indicates not only the first layer is directly on or over the second layer without any intervening layer therebetween, but also the first layer is on or over the second layer with one or more intervening layers between the first and second layers. The memory layer 20 may be formed along a profile of the stack 10. As an embodiment, the memory layer 20 may be deposited along the inner side of the opening OP and an upper surface of the stack 10. FIG. 2B may be a diagram that illustrates a memory layer 20-1 that is disposed along the inner side of the opening OP and a memory layer 20-2 that is disposed along the upper surface of the stack 10.

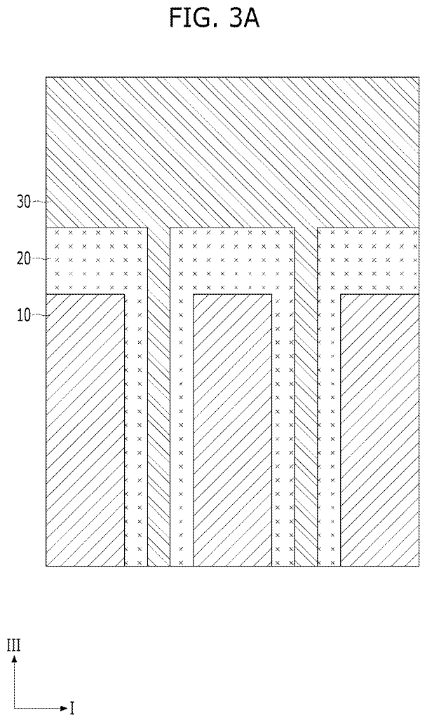

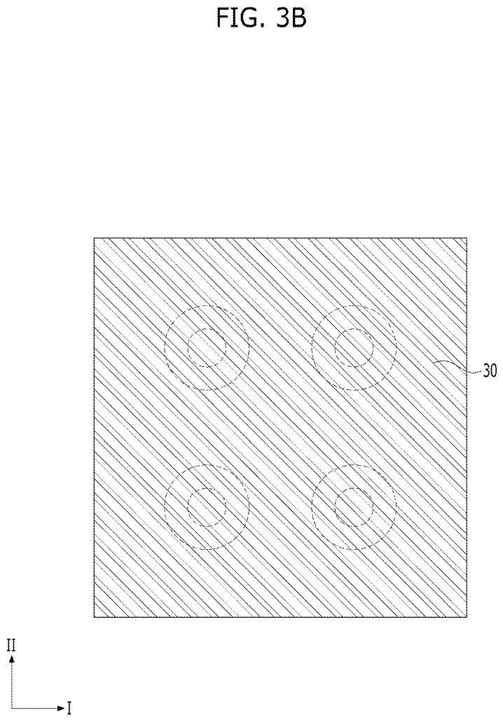

Referring to FIGS. 3A and 3B, a conductive layer 30 may be formed. In this case, the conductive layer 30 may be suitable for forming a gate line, such as a word line or a bit line. The conductive layer 30 may include a conductive material, such as polysilicon or metal. The conductive layer 30 may be formed on the memory layer 20. The conductive layer 30 may be deposited along a profile of the memory layer 20. The conductive layer 30 may be formed within the opening OP and over the stack 10. The memory layer 20 and the conductive layer 30 may have different hardness values. As an embodiment, the hardness of the memory layer 20 may be smaller than the hardness of the conductive layer 30.

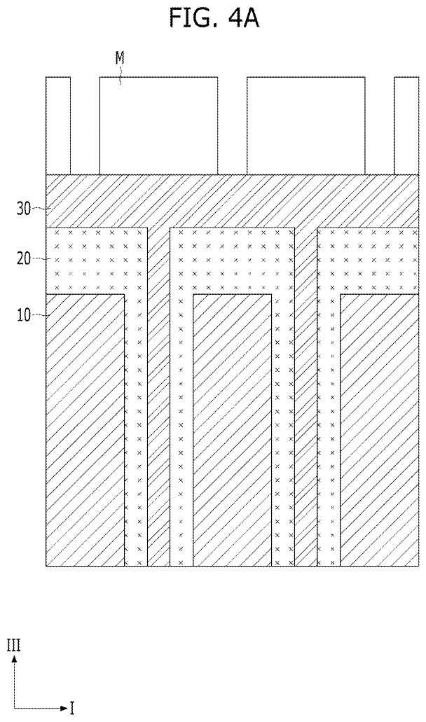

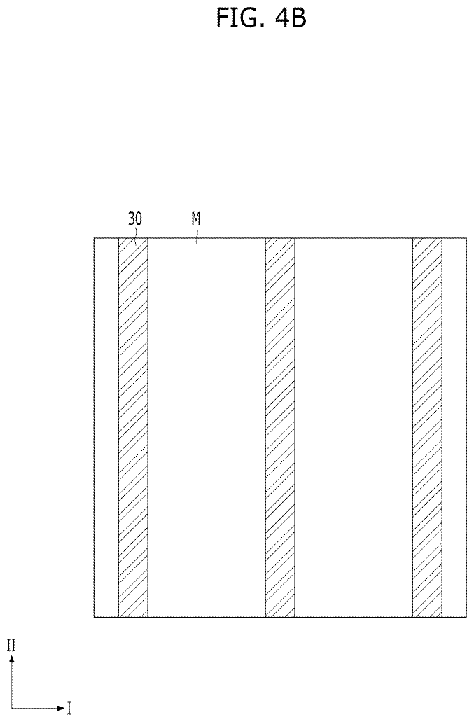

Referring to FIGS. 4A and 4B, a mask pattern M may be formed. As an embodiment, after a mask layer is formed on the conductive layer 30, the mask pattern M may be formed by patterning the mask layer. The mask pattern M may have a form in which the mask pattern covers the openings OP and at least partially exposes an area between the openings OP. As an embodiment, the mask pattern M may include line patterns that extend in the second direction II, and may expose a part of the conductive layer 30 between the line patterns.

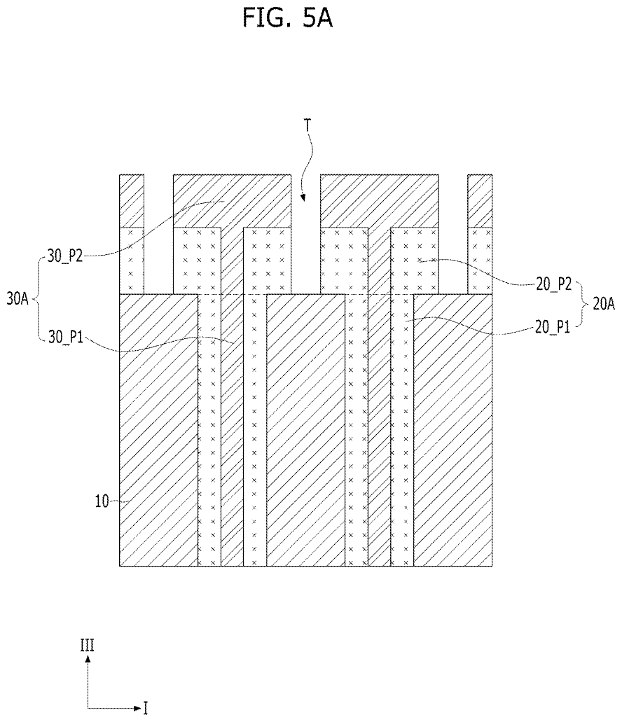

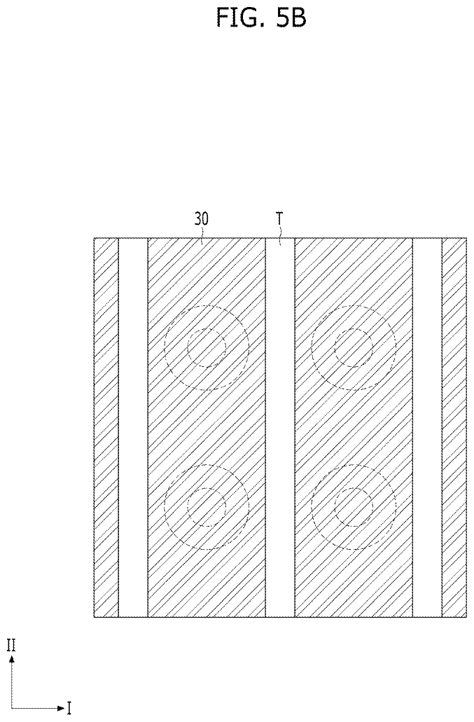

Referring to FIGS. 5A and 5B, a trench T may be formed by etching the conductive layer 30 and the memory layer 20 by using the mask pattern M as an etch barrier. Accordingly, a conductive pattern 30A, including a first part 30_P1 within the opening OP and a second part 30_P2 that is connected to the first part 30_P1 and that is disposed over the stack 10, may be formed. In a cross section that is defined in the first direction I and the third direction III, the conductive pattern 30A may have a T shape. A memory pattern 20A, including a first part 20_P1 within the opening OP and a second part 20_P2 that is connected to the first part 20_P1 and that is disposed over the stack 10, may be formed. The conductive patterns 30A may be separated from each other by the trench T. The memory patterns 20A may be separated from each other by the trench T. Next, the mask pattern M may be removed.

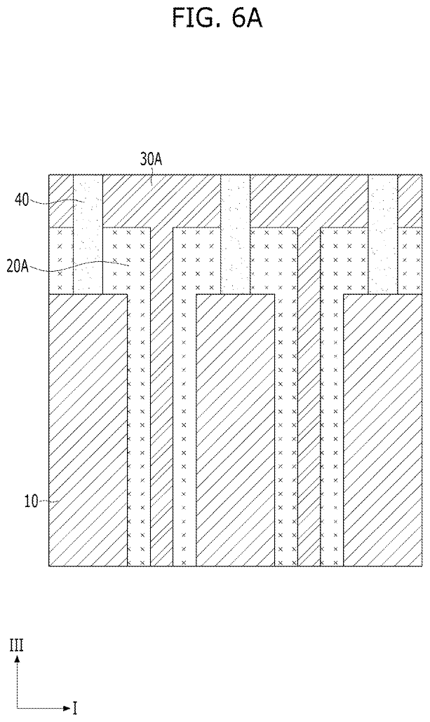

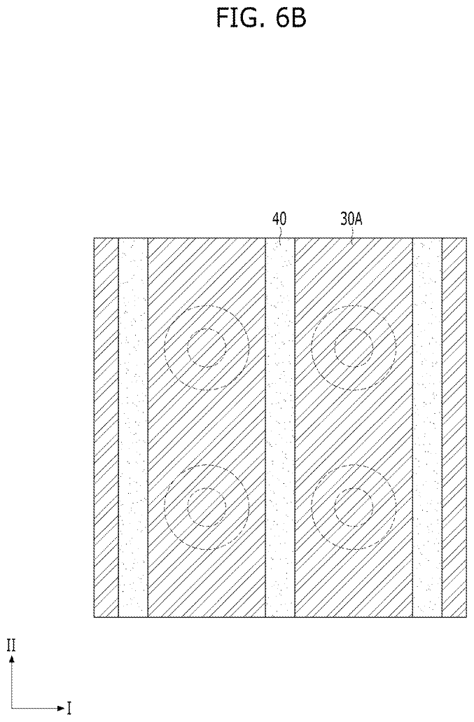

Referring to FIGS. 6A and 6B, an isolation structure 40 may be formed within the trench T. Specifically, the isolation structure 40 may be formed in the trench T that corresponds to a space from which the conductive layer 30 and the memory layer 20 have been etched using the mast pattern M. For example, the isolation structure 40 may be formed between an adjacent pair of second parts 30_P2 of the conductive patterns 30A disposed over the stack 10, and between an adjacent pair of second parts 20_P2 of the memory patterns 20A disposed over the stack 10. The isolation structure 40 may include a material having greater hardness than the memory pattern 20A. As an embodiment, the isolation structure 40 may include an insulating material, such as oxide or nitride.

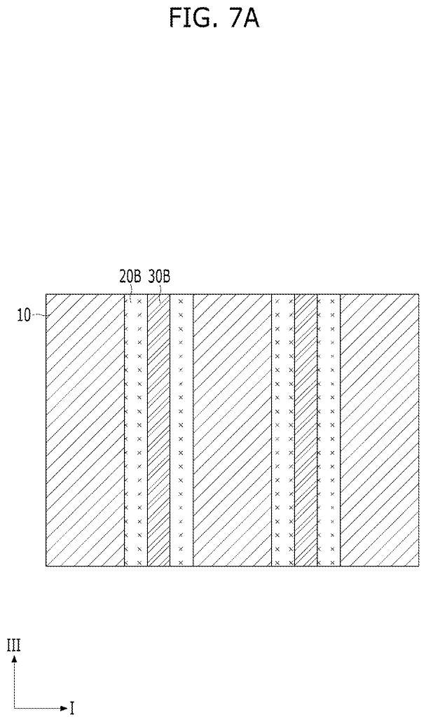

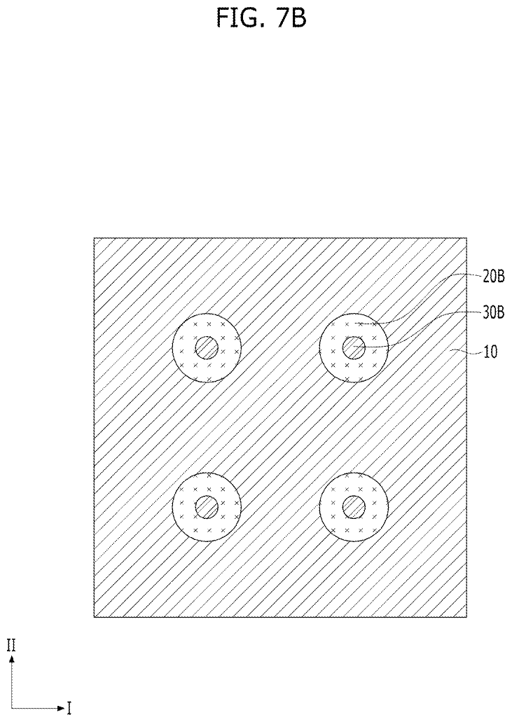

Referring to FIGS. 7A and 7B, the conductive pattern 30A and the memory pattern 20A may be planarized until the stack 10 is exposed. The planarization process may be performed by using a chemical mechanical polishing (CMP) process. Accordingly, a conductive pattern 30B and a memory pattern 20B may be formed within the opening OP. In this case, the conductive pattern 30B may be a bit line.

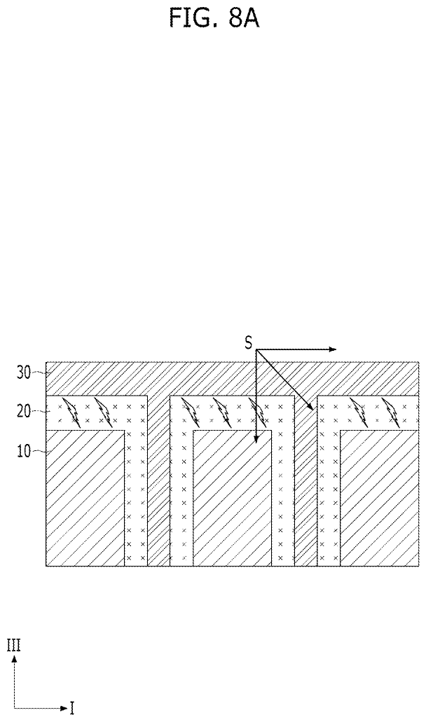

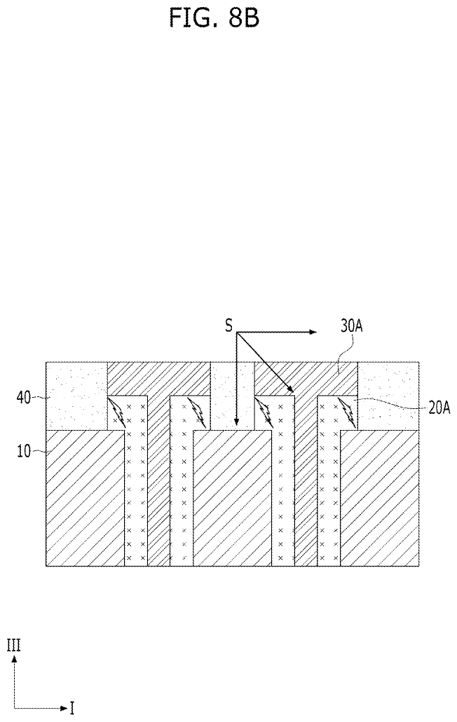

FIGS. 8A and 8B are diagrams for describing a planarization process according to an embodiment of the present disclosure.

FIG. 8A may illustrate the amount of stress that is applied to the memory layer 20 when a planarization process is performed without forming the isolation structure 40. Since the planarization process is performed until the stack 10 is exposed, mechanical stress S having an amount corresponding to the area of the memory layer 20 that is formed on the stack 10 may be transferred to the memory layer 20. FIG. 8B may illustrate the amount of stress that is applied to the memory pattern 20A when a planarization process is performed after the isolation structure 40 is formed. Since the planarization process is performed until the stack 10 is exposed, mechanical stress S having an amount corresponding to the area of the memory pattern 20A that is formed on the stack 10 may be transferred to the memory pattern 20A.

That is, the area of the memory pattern 20A in FIG. 8B has been reduced by forming the isolation structure 40 compared to that of the memory layer 20 in FIG. 8A. Accordingly, a manufacturing method of performing a planarization process according to the embodiment of FIG. 8B can reduce physical stress that is applied to the memory pattern 20A, compared to a manufacturing method of performing a planarization process without forming the isolation structure 40. In addition, without wishing to be limited by theory, the isolation structure 40 may include a material having an elastic modulus greater than that of the memory pattern 20A. As a result, the isolation structure 40 may support a relatively large amount of force exerted thereon when a planarization process is performed, thereby reducing the amount of stress that is applied to the memory pattern 20A. Furthermore, the isolation structure 40 including a material having greater hardness than the memory pattern 20A may also play a role to distribute the physical stress that is applied to the memory pattern 20A.

As a result, the manufacturing method according to an embodiment of the present disclosure can reduce physical stress that occurs in a planarization process because the planarization process is performed after the isolation structure is formed. Furthermore, the manufacturing method can reduce a process risk, such as a film lifting phenomenon, by reducing physical stress that occurs in a planarization process.

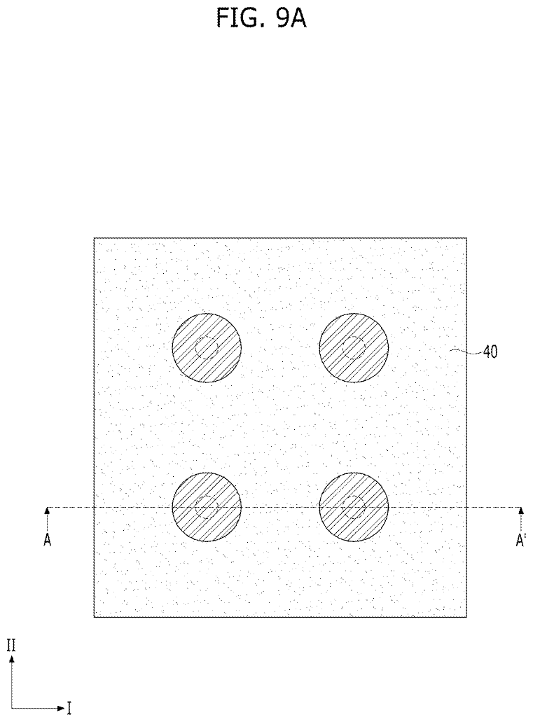

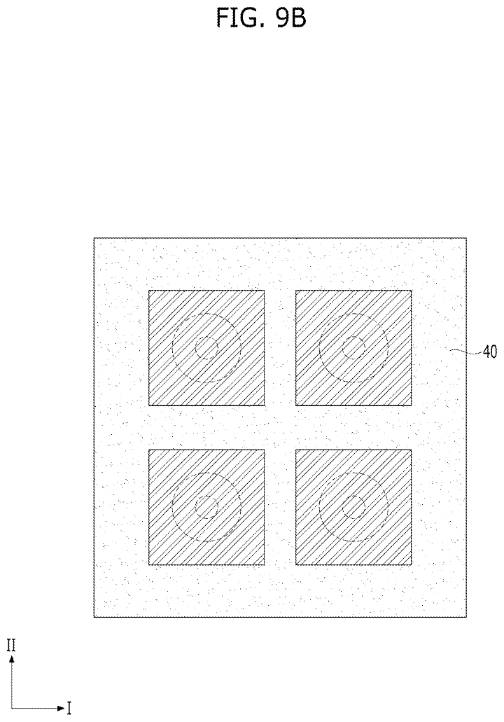

FIGS. 9A and 9B are plan views of an isolation structure according to another embodiment of the present disclosure.

Referring to FIG. 9A, the isolation structure 40 may include an opening form having the same size and shape as the openings OP. Therefore, an area between the openings OP, that is, the conductive layer 30 and the memory layer 20 that are formed over the stack 10, may be removed by the isolation structure 40. Furthermore, the memory layers 20 that are formed within the openings OP, respectively, may be separated from each other by the isolation structure 40.

Referring to FIG. 9B, the isolation structure 40 may have a polygon (e.g., a quadrangle) form that surrounds the openings OP. Therefore, the isolation structure 40 may remove an area between the openings OP, that is, parts of the conductive layer 30 and the memory layer 20 that are formed over the stack 10. Accordingly, the conductive layer 30 and the memory layer 20 that are formed within the polygon may be separated from each other by the isolation structure 40.

As in FIGS. 6B, 9A, and 9B, the isolation structure 40 may be for removing parts or all of the conductive layer 30 and the memory layer 20 that are formed over the stack 10, and may be implemented in various forms.

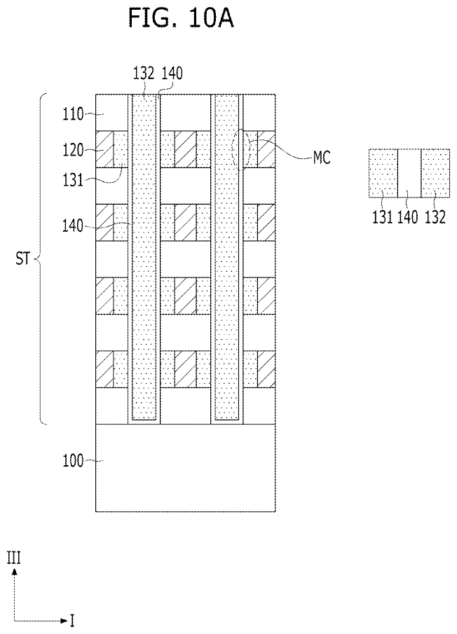

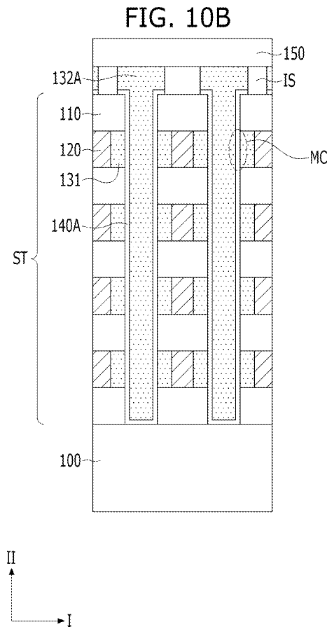

FIGS. 10A and 10B are diagrams for describing a semiconductor device according to an embodiment of the present disclosure. Hereinafter, contents that are redundant with the aforementioned contents may be omitted for the interest of brevity.

Referring to FIG. 10A, a semiconductor device according to an embodiment of the present disclosure may include a substrate 100, a first insulating layer 110, a second insulating layer 120, a first conductive layer 131, a second conductive layer 132, and a memory layer 140.

The first insulating layers 110 and the second insulating layers 120 may be alternately stacked over the substrate 100. The first conductive layers 131 may each be disposed between the second insulating layer 120 and each of the second conductive layers 132. In this case, the first conductive layers 131 may each be a word line. As an embodiment, the first conductive layers 131 may include a conductive material, such as polysilicon or metal. The first insulating layers 110 may be suitable for mutually insulating the first conductive layers 131 that have been stacked. The second insulating layers 120 may be for mutually insulating the first conductive layers 131 that are adjacent to each other in a first direction I. As an embodiment, the first insulating layers 110 and the second insulating layers 120 may each include an insulating material, such as oxide, nitride, or an air gap.

The second conductive layer 132 and the memory layer 140 may penetrate the first insulating layer 110 and the first conductive layers 131, and may extend in a third direction III. The second conductive layer 132 may be a bit line.

A memory cell MC may be disposed at an area in which the first conductive layer 131 and the second conductive layer 132 intersect each other. The memory cell MC may include the first conductive layer 131, the second conductive layer 132, and the memory layer 140.

The memory layer 140 may include a floating gate, polysilicon, a charge trap material, nitride, a variable resistance material, or a phase change material. As an embodiment, the memory layer 140 may include a chalcogenide material. The memory layer 140 may have two states depending on an electrical signal that is provided by a word line and a bit line. For example, the state of the memory layer 140 may change into a reset state or a set state through a program operation. The reset state and the set state may be states having different resistance levels. For example, the reset and set states may be states having different phases.

Referring to FIG. 10B, the semiconductor device according to an embodiment of the present disclosure may further include an isolation structure IS that is formed over the first insulating layer 110. A second conductive pattern 132A may have a cross section having a T shape, and may include a first part within a stack ST and a second part over the stack ST. A memory pattern 140A may include a first part within the stack ST and a second part within the stack ST. Wiring 150 may be connected to the isolation structure IS and the second conductive patterns 132A. Wiring 150 may be electrically connected to the second conductive pattern 132A, that is, a bit line. The bit line and a peripheral circuit may be electrically connected by the wiring 150.

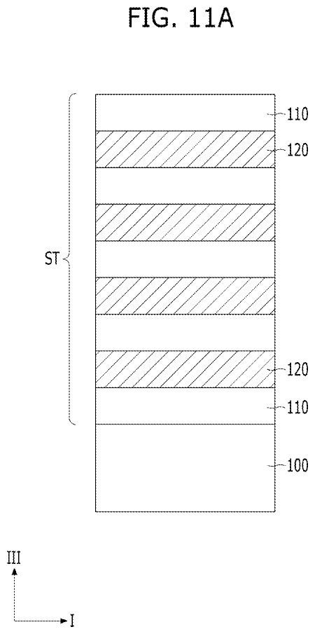

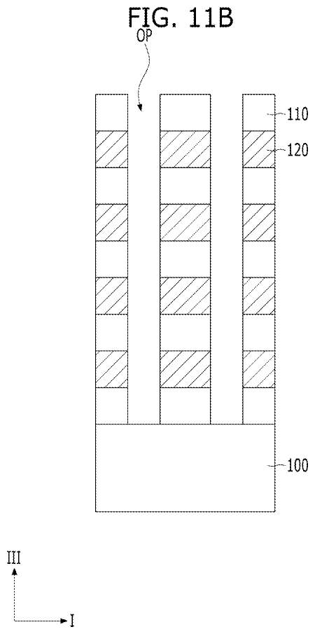

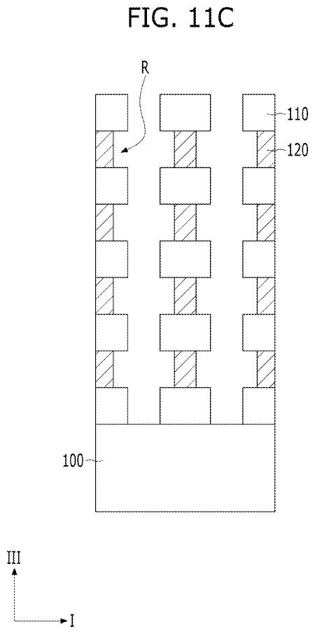

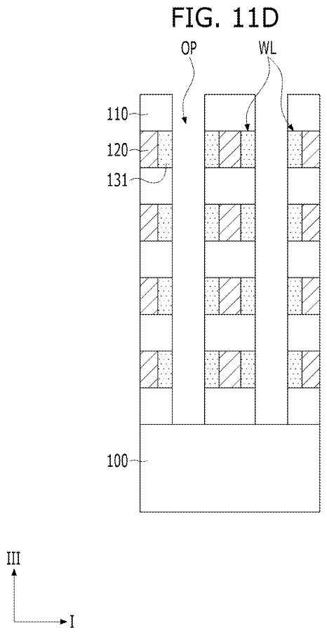

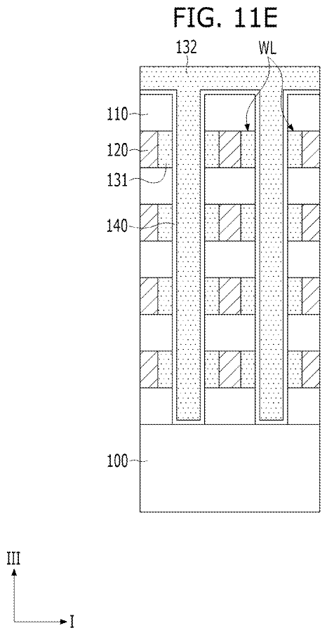

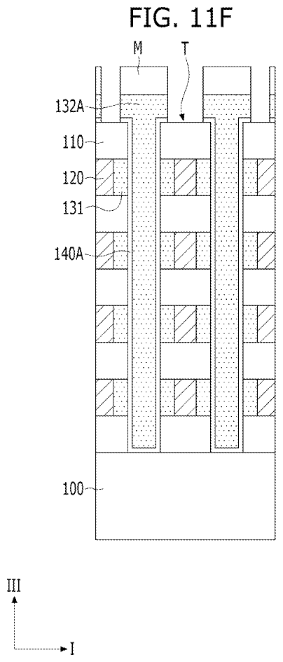

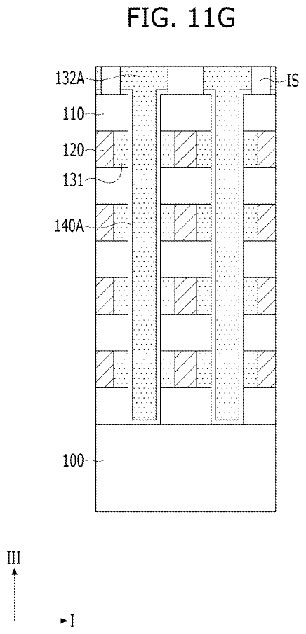

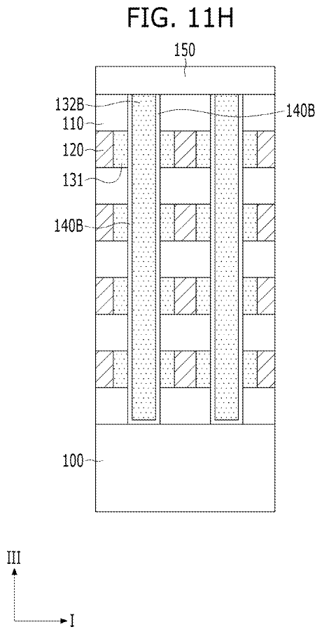

FIGS. 11A, 11B, 11C, 11D, 11E, 11F, 11G, 11H, 11I, and 11J are diagrams for describing a method of manufacturing a semiconductor device according to an embodiment of the present disclosure.

Referring to FIG. 11A, a stack ST may be formed. The stack ST may be formed by alternately stacking first material layers 110 and second material layers 120 over a semiconductor substrate 100. As an embodiment, the first material layers 110 may each include a material having a higher etch selectivity ratio than each of the second material layers 120. The first material layers 110 may each include oxide, and the second material layers 120 may each include nitride. The first material layers 110 may each include nitride, and the second material layers 120 may each include oxide.

Referring to FIG. 11B, an opening OP may be formed within the stack ST. As an embodiment, a plurality of openings OP may be arranged in a first direction I and a second direction II that intersects the first direction I. The opening OP may extend in a third direction III within the stack ST. In this case, the third direction III may be a direction orthogonal to a plane that is defined in the first direction I and the second direction II.

Referring to FIG. 11C, spaces (e.g., recesses) R in which a word line will be disposed may be formed within the opening OP. As an embodiment, the recesses R may be formed by selectively etching the second material layer 120 within the opening OP.

Referring to FIG. 11D, a first conductive layer 131 may be formed within each of the recesses R. In this case, the first conductive layer 131 may be a word line WL. The first conductive layer 131 may include a conductive material, such as polysilicon or metal.

Referring to FIG. 11E, a memory layer (or initial memory layer) 140 may be formed. The memory layer 140 may include a floating gate, polysilicon, a charge trap material, nitride, a variable resistance material, or a phase change material. As an embodiment, the memory layer 140 may be formed within the opening OP and on the stack ST. For example, the memory layer 140 may be deposited along the inner side of the opening OP and an upper surface of the stack ST.

Next, a second conductive layer (or initial second conductive layer) 132 may be formed. The second conductive layer 132 may be for forming a bit line. The second conductive layer 132 may include a conductive material, such as polysilicon or metal. As an embodiment, the second conductive layer 132 may be formed on the memory layer 140. The second conductive layer 132 may be deposited along a profile of the memory layer 140. The second conductive layer 132 may be formed within the opening OP and over the stack ST. The memory layer 140 and the second conductive layer 132 may have different hardness values. As an embodiment, the hardness of the memory layer 140 may be smaller than the hardness of the second conductive layer 132.

Referring to FIG. 11F, a mask pattern M may be formed. As an embodiment, after a mask layer is formed on the second conductive layer 132, the mask pattern M may be formed by patterning the mask layer. The mask pattern M may cover the memory layer 140 and the second conductive layer 132 that are formed within each of the openings OP, and may have a form in which the mask pattern at least partially exposes an area of the second conductive layer 132, which is formed over the stack ST. The mask pattern M may include one or more line patterns that each extend in the second direction II, and may expose the second conductive layer 132 between the line patterns. For example, the mask pattern M may expose one or more parts of the second conductive layer 132 formed over the stack ST, such that each of these parts is positioned between a pair of adjacent line patterns of the mask pattern M.

Next, a trench T may be formed by etching the second conductive layer 132 and the memory layer 140 with the mask pattern M as an etch barrier. Parts of the second conductive layer 132 and the memory layer 140 that are formed over the stack ST may be removed through the trench T, so that a second conductive pattern 132A and a memory pattern 140A may be formed. Next, the mask pattern M may be removed. The second conductive pattern 132A may have a cross section having a T shape, and may include a first part within the opening OP and a second part that is connected to the first part and that is disposed over the stack ST. The memory pattern 140A may include a first part within the opening OP and a second part that is connected to the first part and that is disposed over the stack ST.

Referring to FIG. 11G, an isolation structure IS may be formed within the trench T. For example, the isolation structure IS may be formed between the second parts of an adjacent pair of the second conductive patterns 132A and between the second parts of an adjacent pair of the memory patterns 140A. The isolation structure IS may include a material having greater hardness than the memory layer 140. As an embodiment, the isolation structure IS may include an insulating material, such as oxide or nitride.

Referring to FIG. 11H, the second conductive pattern 132A and the memory pattern 140A may be planarized until the stack ST is exposed. For example, the second conductive pattern 132A, the isolation structure IS, and the memory pattern 140A may be planarized until the stack ST is exposed to remain the first part of the second conductive pattern 132A within the opening OP and the first part of the memory pattern 140A within the opening OP. A chemical mechanical polishing (CMP) process may be used as the planarization process. Next, a metal process of connecting wiring 150 to the second conductive layer 132B within the opening OP may be performed. For example, the wiring 150 may be connected to the first parts of the second conductive pattern 132A remaining within the opening OP. In this case, the wiring 150 may connect a bit line (e.g., the second conductive layer 132 in FIG. 10A) and a peripheral circuit.

For reference, the planarization process may be omitted. As an embodiment, after the isolation structure IS is formed, the wiring may be formed so that the wiring is connected to the second conductive pattern 132A having a T shape. Accordingly, the semiconductor device that has been described with reference to FIG. 10B can be manufactured.

The method of manufacturing a semiconductor device according to an embodiment of the present disclosure can reduce physical stress that is applied to the memory pattern 140A due to the planarization process because the planarization process is performed until the stack ST is exposed in the state in which the isolation structure IS has been formed. Furthermore, the method can reduce a process risk by preventing a film lifting phenomenon of the memory layer 140 attributable to the planarization process.

The method of manufacturing a semiconductor device according to an embodiment of the present disclosure is not limited to the method of forming the word line (i.e., the first conductive layer 131), the memory cell (i.e., the memory cell MC including the memory layer 140 that is disposed between the first and second conductive layers 131 and 132), and the bit line (i.e., the second conductive layer 132), and may be applied to a manufacturing method of simultaneously planarizing a plurality of other layers having different hardness. Accordingly, a risk of a layer that has relatively low hardness being damaged in a planarization process can be significantly reduced.

Accordingly, the manufacturing method according to the present disclosure may also be applied to a technology for forming a word line, a memory cell, and a bit line by using a manufacturing method different from the method of manufacturing a semiconductor device according to an embodiment of the present disclosure. More specifically, although a different method of manufacturing a word line, a memory cell, and a bit line is used, those skilled in the art can practice the manufacturing method of forming an isolation structure according to an embodiment of the present disclosure to remove a memory layer and a conductive layer that are formed over a stack for forming the memory layer and the conductive layer within an opening in the stack.

Although embodiments according to the technical spirit of the present disclosure have been described above with reference to the accompanying drawings, the embodiments have been provided to merely describe specific embodiments according to the concept of the present disclosure, and embodiments of the present disclosure are not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may belong to the scope of the present disclosure.

What is claimed is:

1. A manufacturing method comprising:
forming an opening within a stack;
forming a variable resistance layer within the opening and on the stack;
forming a conductive layer on the variable resistance layer;
forming a conductive pattern comprising a first part within the opening and a second part on the stack, by etching the conductive layer;
forming a variable resistance pattern comprising a first part within the opening and a second part on the stack, by etching the variable resistance layer; and
planarizing the conductive pattern and the variable resistance pattern until the stack is exposed.

2. The manufacturing method of claim 1, further comprising forming an isolation structure in a space from which the conductive layer and the variable resistance layer have been etched, the isolation structure having greater hardness than the variable resistance layer.

3. The manufacturing method of claim 2, wherein the forming of the isolation structure comprises:
forming a mask pattern that covers the opening and that exposes a part of the conductive layer;
forming a trench by etching the conductive layer and the variable resistance layer by using the mask pattern as an etch barrier; and
forming the isolation structure within the trench.

4. The manufacturing method of claim 3, wherein the forming of the mask pattern comprises:
forming a mask layer on the conductive layer; and
patterning the mask layer to form the mask pattern that covers the opening and exposes the part of the conductive layer.

5. A method of manufacturing a semiconductor device, comprising:
forming a stack comprising first material layers and second material layers that are alternately stacked;
forming an opening within the stack;
forming a memory layer within the opening and on the stack;
forming a first conductive layer on the memory layer;
forming an isolation structure within the memory layer and the first conductive layer; and
planarizing the first conductive layer, the memory layer, and the isolation structure until the stack is exposed.

6. The method of claim 5, wherein the memory layer comprises a variable resistance material.

7. The method of claim 5, wherein the isolation structure comprises a material having greater hardness than the memory layer.

8. The method of claim 5, wherein the forming of the isolation structure comprises:
forming a mask pattern on the first conductive layer;
forming a trench by etching the first conductive layer and the memory layer using the mask pattern as an etch barrier; and
forming the isolation structure within the trench.

9. The method of claim 8, wherein the mask pattern covers the opening and exposes a part of the first conductive layer formed over the stack.

10. The method of claim 5, further comprising:
selectively etching the first material layers; and
forming a second conductive layer in a space that has been selectively etched.

11. A method of manufacturing a semiconductor device, comprising:
forming a stack;
forming an opening within the stack;
forming a memory layer within the opening and on the stack;
forming a conductive layer on the memory layer;
forming conductive patterns and a trench that separates the conductive patterns from each other by etching the conductive layer, each of the conductive patterns comprising a first part within the opening and a second part that is connected to the first part and disposed over the stack; and
forming an isolation structure within the trench.

12. The method of claim 11, wherein the isolation structure has greater hardness than the memory layer.

13. The method of claim 11, wherein the forming of the trench comprises:
forming a mask pattern that covers the opening and that exposes parts of the conductive patterns that are disposed over the stack; and
forming the trench by etching a part of the second part and the memory layer using the mask pattern as an etch barrier.

14. The method of claim 11, wherein the wiring is connected to the first part of each of the conductive patterns.

15. The method of claim 14, further comprising forming memory patterns by etching the memory layer, each of the memory patterns comprising a first part within the opening and a second part that is connected to the first part and disposed over the stack,
wherein the trench separates the memory patterns from each other.

16. The method of claim 15, wherein the isolation structure is formed between the second parts of an adjacent pair of the conductive patterns and between the second parts of an adjacent pair of the memory patterns.

17. The method of claim 11, wherein the wiring is connected to the isolation structure and the conductive patterns.

18. The method of claim 17, wherein the wiring is electrically connected to the conductive patterns and a peripheral circuit.
